(19) United States
(12) Patent Application Publication
(10) Pub. No.: US 2017/0099048 A1
(43) Pub. Date: Apr. 6, 2017

(54) POWER COMBINING DEVICE

(71) Applicant: ELECTRONICS AND TELECOMMUNICATIONS RESEARCH INSTITUTE, Daejeon (KR)

(72) Inventors: Tae Wook KANG, Daejeon (KR); Sung Eun KIM, Daejeon (KR)

(21) Appl. No.: 15/068,057

(22) Filed: Mar. 11, 2016

(30) Foreign Application Priority Data
Oct. 5, 2015 (KR) 10-2015-0139825

(51) Int. Cl. H03K 17/30; H03K 3/037; H03K 5/24

(52) U.S. Cl. CPC H03K 17/302; H03K 5/24; H03K 3/037

(57) ABSTRACT

Provided is a power combining device including a comparison circuit configured to output low power comparison signals by comparing a first threshold voltage and levels of voltages of storage elements charged by external power sources according to low power control signals and output high power comparison signals by comparing a second threshold voltage and the levels of the voltages according to high power control signals, a switching signal generation circuit configured to output low power switching signals based on the low power comparison signals and output high power switching signals based on the high power comparison signals, and a switching circuit configured to select loads electrically coupled with the storage elements based on the low power switching signals and the high power switching signals.

### CROSS-REFERENCE TO RELATED APPLICATIONS

This U.S. non-provisional patent application claims priority under 35 U.S.C. §119 of Korean Patent Application No. 10-2015-0139825, filed on Oct. 5, 2015, the entire contents of which are hereby incorporated by reference.

### BACKGROUND

The present disclosure herein relates to a power combining device.

Recently, with the development of telecommunication technologies, various types of electronic devices have emerged. For example, as electronic devices such as portable electronic devices implement user-friendly ubiquitous computing, their demands have been increased exponentially. Portable electronic devices may include a portable power source such as a battery. Batteries may be a one-time use or require regular charging. Accordingly, the necessity of energy harvesting in electronic devices has emerged. Energy harvesting is a technique for re-harvesting wasted energy around such as light, heat, and vibration and converting it into electrical energy. Suggested is an energy harvesting system that supplies power by converting various energy sources into electrical energy through a photovoltaic or solar device and a piezoelectric device. In order to improve the performance of power supply in an energy harvesting system, when more than two energy sources are used at the same time, the power management and distribution of an energy harvesting system are required to be smooth.

### SUMMARY

The present disclosure herein relates to a power combining device having improved efficiency, which efficiently manages power delivered from an external power source (for example, a harvesting source).

An embodiment of the inventive concept provides a power combining device including: a comparison circuit configured to output low power comparison signals by comparing a first threshold voltage and levels of voltages of storage devices charged by external power sources according to low power control signals and output high power comparison signals by comparing a second threshold voltage and the levels of the voltages according to high power control signals; a switching signal generation circuit configured to output low power switching signals based on the low power comparison signals and output high power switching signals based on the high power comparison signals; and a switching circuit configured to select loads electrically coupled with the storage devices based on the low power switching signals and the high power switching signals.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a block diagram illustrating a power combining device according to an embodiment of the inventive concept;

FIG. 2 is a view illustrating a configuration of a power combining device when the number of external power sources is three according to an embodiment of the inventive concept;

FIG. 3 is a flowchart illustrating a method of operating a power combining device according to an embodiment of the inventive concept;

FIG. 4 is a timing diagram depending on an operation process according to an embodiment of the inventive concept;

FIG. 5 is a view illustrating an internal logic circuit according to an embodiment of the inventive concept; and

FIGS. 6 and 7 are views illustrating a switching signal generation circuit according to an embodiment of the inventive concept.

### DETAILED DESCRIPTION

Hereinafter, it will be described in more detail with reference to the accompanying drawings so that those skilled in the art easily carry out the technical idea of the inventive concept.

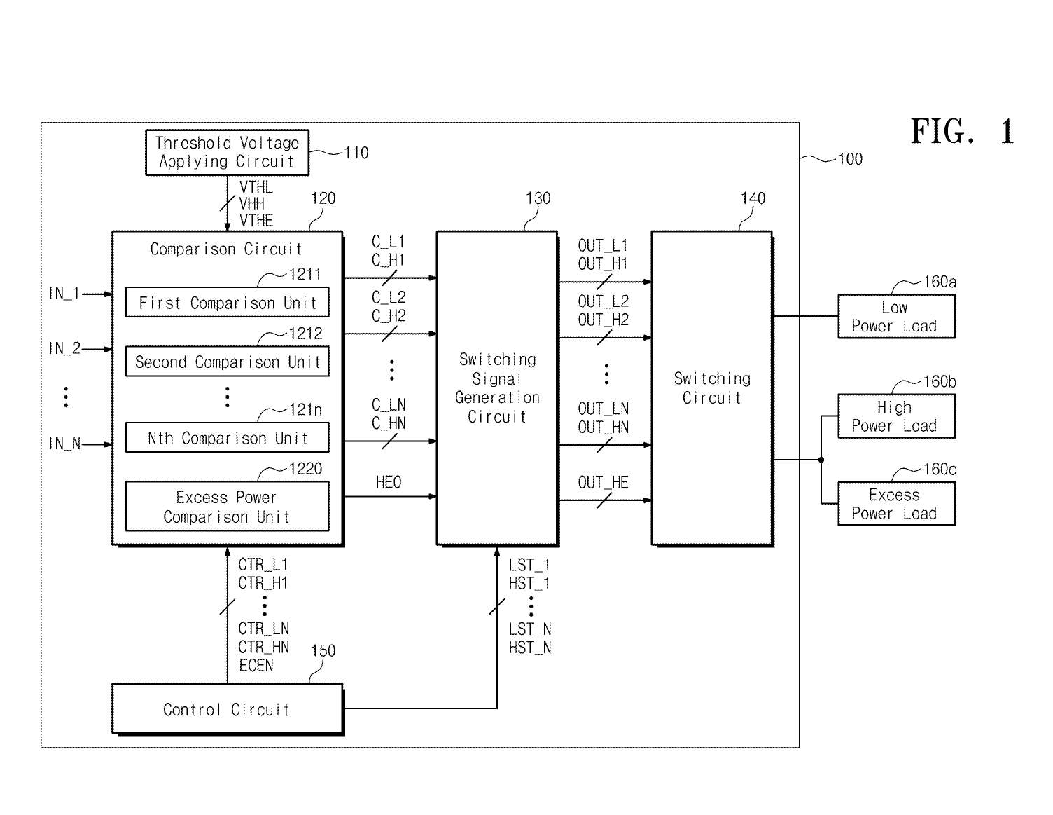

FIG. 1 is a block diagram illustrating a power combining device 100 according to an embodiment of the inventive concept. Referring to FIG. 1, the power combining device 100 includes a threshold voltage applying circuit 110, a comparison circuit 120, a switching signal generation circuit 130, a switching circuit 140, and a control circuit 150.

The threshold voltage applying circuit 110 may generate first to third threshold voltages VTHL, VTHH, and VTHE having different levels and output them to the comparison circuit 120. Additionally, the threshold voltage applying circuit 110 may adjust levels of the first to third threshold voltages VTHL, VTHH, and VTHE and output them according to characteristics of external power sources IN_1 to IN_N.

The comparison circuit 120 may operate first to Nth comparison units 1211 to 121n in response to first to Nth low power control signals CTR_L1 to CTR_LN and first to Nth high power control signals CTR_H1 to CTR_HN. For example, the first low power control signal CTR_L1 and the first high power control signal CTR_H1 may be received by the first comparison unit 1211. For example, the Nth low power control signal CTR_LN and the Nth high power control signal CTR_HN may be received by the Nth comparison unit 121n.

The comparison circuit 120 may output the first to Nth low power comparison signals C_L1 to C_LN and first to Nth high power comparison signals C_H1 to C_HN, which are outputted from the first to Nth comparison units C_L1 to C_LN, in response to the Nth low power control signal CTR_LN and the Nth high power control signal CTR_HN.

The comparison circuit 120 may output the first to Nth low power comparison signals C_L1 to C_LN outputted from the first to Nth comparison units 1211 to 121n according to a comparison result of voltages levels of storage devices in the first to Nth comparison units 1211 to 121n charged by the external power sources IN_1 to IN_N and the first threshold voltage VTHL. Additionally, the first to Nth high power comparison signals C_H1 to C_HN outputted from the first to Nth comparison units 1211 to 121n may be outputted according to a comparison result of voltages levels of storage devices in the first to Nth comparison units 1211 to 121n charged by the external power sources IN_1 to IN_N and the second threshold voltage VTHH. For example, the first comparison unit 1211 may output the first low power comparison signal C_L1 according to the first low power control signal CTR_L1 and output the first high power comparison signal C_H1 according to the first high power control signal CTR_H1. For example, the Nth comparison unit 121n may output the Nth low power comparison signal C_LN according to the Nth low power control signal CTR_LN and output the Nth high power comparison signal C_HN according to the Nth high power control signal CTR_HN.

The comparison circuit 120 may operate an excess power comparison unit 1220 according to an excess signal ECEN generated based on the first to Nth high power control signals CTR_H1 to CTR_HN. For example, when a level of a storage device charged by an external power source IN_i selected from the external power sources IN_1 to IN_N exceeds the third threshold voltage VTHE, the excess power comparison unit 1220 may output an excess power comparison signal HEO in high level in response to an excess signal ECEN outputted from the control circuit 150.

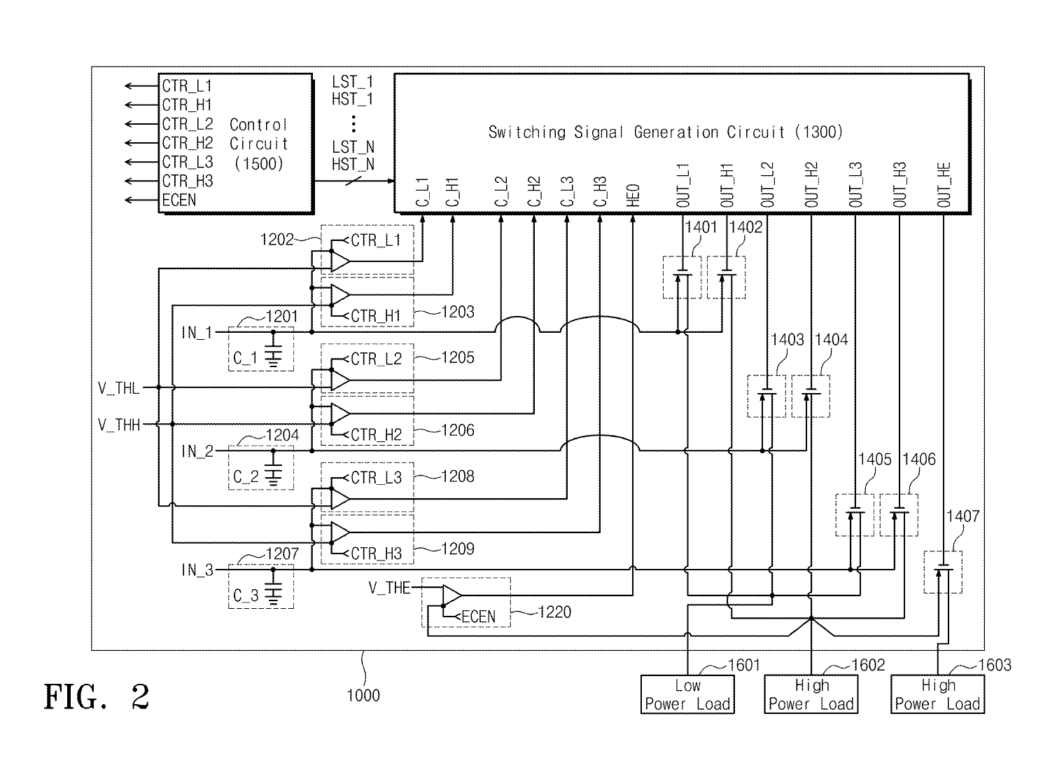

For example, the comparison circuit 120 may be configured with total 2N+1 comparators, including N low power determination comparators for determining whether a voltage level of storage devices charged by the N external power sources IN_1 to IN_N exceeds the first threshold voltage VTHL, N high power determination comparators for determining whether it exceeds the second threshold voltage VTHL, and an excess power comparator for determining whether it exceeds the third threshold voltage VTHE. An internal structure of the comparison circuit 120 will be described in more detail with reference to FIG. 2.

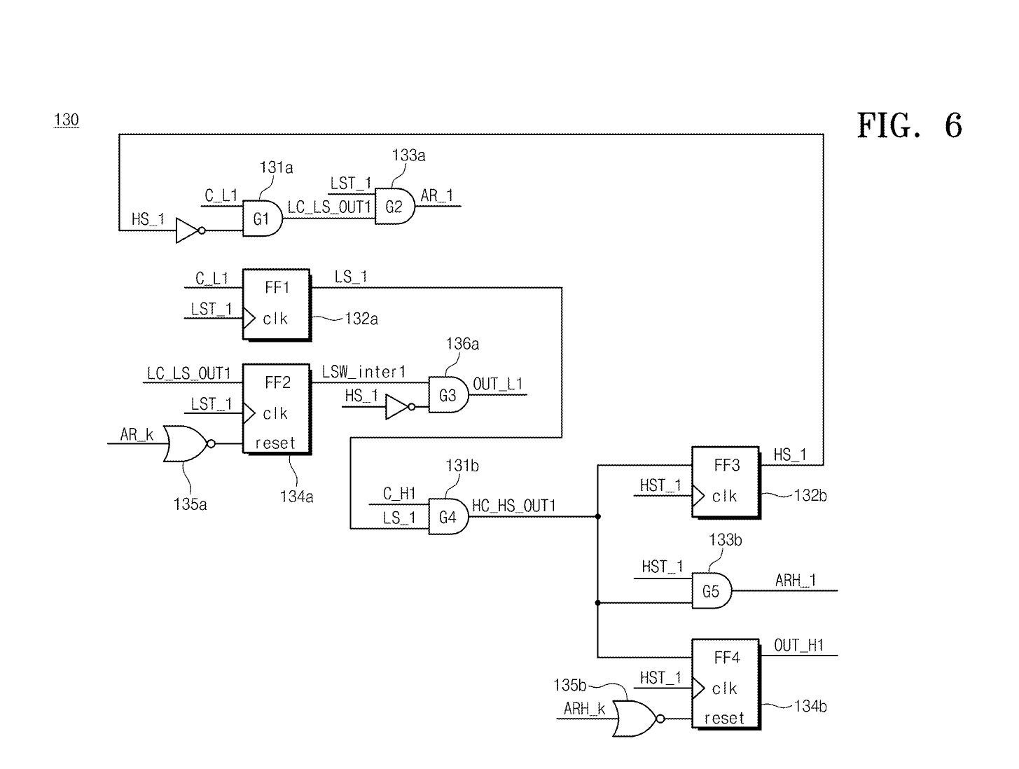

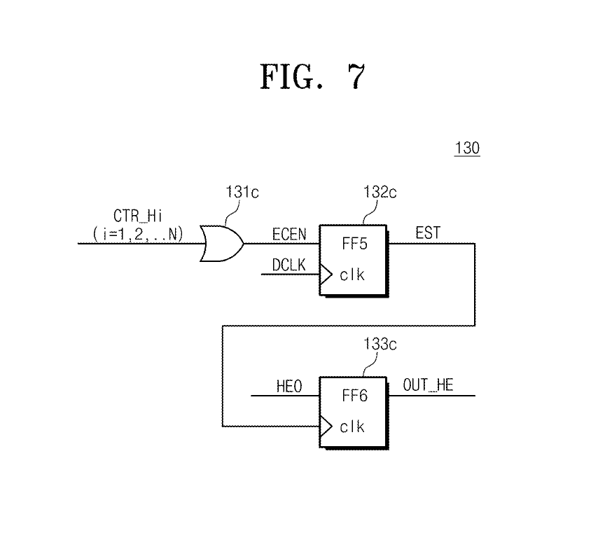

The comparison circuit 120 may output the first to Nth low power switching signals OUT_L1 to OUT_LN and the first to Nth high power switching signals OUT_H1 to OUT_HN in response to first to Nth low power trigger signals LST_1 to LST_N and first to Nth high power trigger signals HST_1 to HST_N, outputted from the control circuit 150, and the first to Nth low power comparison signals C_L1 to C_LN outputted from the comparison circuit 120. An internal structure of the switching signal generation circuit 130 will be described in more detail with reference to FIGS. 6 and 7.

As receiving the first to Nth low power switching signals OUT_L1 to OUT_LN and the first to Nth high power switching signals OUT_H1 to OUT_HN outputted from the switching signal generation circuit 130, the switching circuit 140 may select a load that is electrically coupled to storage devices in the first to Nth comparison units 1211 to 121n charged by the external power sources IN_1 to IN_N.

For example, when a level of a storage device charged by the selected external power source IN_i is higher than the first threshold voltage VTHL and is lower than the second threshold voltage VTHH, a storage device charged by the selected external power source IN_i may be connected to a low power load 160a.

For example, when a level of a storage device charged by the selected external power source IN_i is higher than the first threshold voltage VTHL and the second threshold voltage VTHH, a storage device charged by the selected external power source IN_i may be connected to a high power load 160b.

For example, when a level of a storage device charged by the selected external power source IN_i is higher than the first threshold voltage VTHL, the second threshold voltage VTHH, and the third threshold voltage VTHE, a storage device charged by the selected external power source IN_i may be connected to an excess power load 160c.

The control circuit 150 may output, to the comparison circuit 120, the first to Nth low power control signals CTR_L1 to CTR_LN for controlling low power determination comparators that are respectively disposed in the first to Nth comparison units 1211 to 121n corresponding to the external power sources IN_1 to IN_N.

Additionally, The control circuit 150 may output, to the comparison circuit 120, the first to Nth high power control signals CTR_H1 to CTR_HN for controlling high power determination comparators that are respectively disposed in the first to Nth comparison units 1211 to 121n corresponding to the external power sources IN_1 to IN_N.

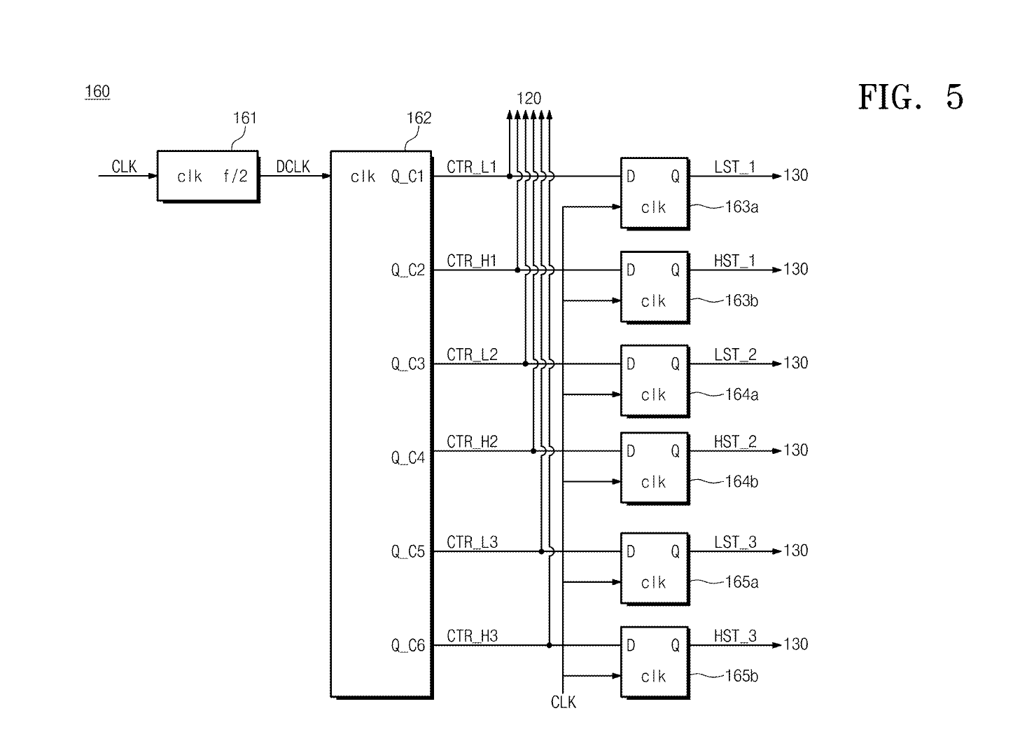

Then, the control circuit 150 may generate first to Nth low power trigger signals LST_1 to LST_N and first to Nth high power trigger signals HST_1 to HST_N and output them to the switching signal generation circuit 130. In this case, the control circuit 150 may be configured with a digital control unit (DCU). Then, the generation processes of the first to Nth low power trigger signals LST_1 to LST_N and the first to Nth high power trigger signals HST_1 to HST_N will be described in detail with reference to FIG. 5.

FIG. 2 is a view illustrating a configuration of a power combining device 1000 when the number of external power sources IN_1 to IN_3 is three.

Referring to FIGS. 1 and 2, the first to third external power sources IN_1 to IN_3 may be identical to each other or different energy sources. The first to third external power sources IN_1 to IN_3 may be provided to respective storage devices 1201, 1204, and 1207 at the same time or with a time difference. The storage devices 1201, 1204, and 1207 may store power supplied from the third external power sources IN_1 to IN_3. For example, the storage devices 1201, 1204, and 1207 may use a chargeable or dischargeable capacitor C.

The first storage device 1201 may be connected to an output terminal of the first external power source IN_1 and may be charged by the first external power source IN_1. For example, when the first low power control signal CTR_L1 is high level, the first low power determination comparator 1202 may be activated. On the other hand, when the first low power control signal CTR_L1 is low level, the first low power determination comparator 1202 may be deactivated.

For example, when the first high power control signal CTR_H1 is high level, the first high power determination comparator 1203 may be activated. On the other hand, when the first high power control signal CTR_H1 is low level, the first high power determination comparator 1202 may be deactivated.

As mentioned above, the power combining device 1000 may prevent unnecessary power consumption by deactivating an unnecessary operation of a comparator in a corresponding section.

For example, the activated first low power determination comparator 1202 may compare a voltage level of the first storage device 1201 charged by the first external power source IN_1 with the first threshold voltage VTHL. That is, when a voltage level of the first storage device 1201 is higher than the first threshold voltage VTHL, the activated first low power determination comparator 1202 may output the first low power comparison signal C_L1 as a high level signal, and when a voltage level of the first storage device 1201 is lower than the first threshold voltage VTHL, output the first low power comparison signal C_L1 as a low level signal.

For example, the activated first high power determination comparator 1203 may compare a voltage level of the first storage device 1201 charged by the first external power source IN_1 with the second threshold voltage VTHH. That is, when a voltage level of the first storage device 1203 is higher than the second threshold voltage VTHH, the activated first high power determination comparator 1203 may output the first high power comparison signal C_H1 as a high level signal, and when a voltage level of the first storage device 1201 is lower than the second threshold voltage VTHH, output the first high power comparison signal C_H1 as a low level signal.

For example, the first storage device 1201, the first low power determination comparator 1202, and the first high power determination comparator 1203 may form the first comparison unit 1211 of FIG. 1.

The second storage device 1204 may be connected to an output terminal of the second external power source IN_2 and may be charged by the second external power source IN_2. For example, when the second low power control signal CTR_L2 is high level, the second low power determination comparator 1205 may be activated. On the other hand, when the second low power control signal CTR_L2 is low level, the second low power determination comparator 1205 may be deactivated.

For example, when the second high power control signal CTR_H2 is high level, the second high power determination comparator 1206 may be activated. On the other hand, when the second high power control signal CTR_H2 is low level, the second high power determination comparator 1206 may be deactivated.

For example, the activated second low power determination comparator 1205 may compare a voltage level of the second storage device 1204 charged by the second external power source IN_2 with the first threshold voltage VTHL. That is, when a voltage level of the second storage device 1204 is higher than the first threshold voltage VTHL, the activated second low power determination comparator 1205 may output the second low power comparison signal C_L2 as a high level signal, and when a voltage level of the second storage device 1204 is lower than the first threshold voltage VTHL, output the second low power comparison signal C_L2 as a low level signal.

For example, the activated second high power determination comparator 1206 may compare a voltage level of the second storage device 1204 charged by the second external power source IN_2 with the second threshold voltage VTHH. That is, when a voltage level of the second storage device 1204 is higher than the second threshold voltage VTHH, the activated second high power determination comparator 1206 may output the second high power comparison signal C_H2 as a high level signal, and when a voltage level of the second storage device 1204 is lower than the second threshold voltage VTHH, output the second high power comparison signal C_H2 as a low level signal.

For example, the second storage device 1204, the second low power determination comparator 1205, and the second high power determination comparator 1206 may form the second comparison unit 1212 of FIG. 1.

The third storage device 1207 may be connected to an output terminal of the third external power source IN_3 and may be charged by the third external power source IN_3. For example, when the third low power control signal CTR_L3 is high level, the third low power determination comparator 1208 may be activated. On the other hand, when the third low power control signal CTR_L3 is low level, the third low power determination comparator 1208 may be deactivated.

For example, the third high power determination comparator 1209 may operate only when the third high power control signal CTR_H3 is high level. On the other hand, when the third high power control signal CTR_H3 is low level, the third high power determination comparator 1209 may be deactivated.

For example, the activated third low power determination comparator 1208 may compare a voltage level of the third storage device 1207 charged by the third external power source IN_3 with the first threshold voltage VTHL. That is, when a voltage level of the third storage device 1207 is higher than the first threshold voltage VTHL, the activated third low power determination comparator 1208 may output the third low power comparison signal C_L3 as a high level signal, and when a voltage level of the third storage device 1207 is lower than the first threshold voltage VTHL, output the third low power comparison signal C_L3 as a low level signal.

For example, the activated third high power determination comparator 1209 may compare a voltage level of the third storage device 1207 charged by the third external power source IN_3 with the second threshold voltage VTHH. That is, when a voltage level of the third storage device 1207 is higher than the third threshold voltage VTHH, the activated third high power determination comparator 1209 may output the third high power comparison signal C_H3 as a high level signal, and when a voltage level of the third storage device 1207 is lower than the second threshold voltage VTHH, output the third high power comparison signal C_H3 as a low level signal.

For example, the third storage device 1207, the third low power determination comparator 1208, and the third high power determination comparator 1209 may form the third comparison unit (not shown) of FIG. 1.

The excess comparator 1220 may operate when an excess signal ECEN is high level. The excess power comparator 1220 may compare a level of voltage applied to the high power load 1620 according to the excess signal ECEN with the third threshold voltage VTHE. For example, when a level of voltage applied to the high power load 1620 is higher than the third threshold voltage VTHE, the excess power comparator 1220 may output an excess comparison signal HEO as a high level signal.

As mentioned above, an internal structure of the switching signal generation circuits 130 and 1300 will be described in more detail with reference to FIGS. 6 and 7.

In the first low power switch 1401, the first low power switching signal OUT_L1 is received by a gate, and one end is connected to the first storage device 1201 and the other end is connected to the low power load 1601. For example, when the first low power switching signal OUT_L1 received by a gate is a high level signal, the power charged to the first storage device 1201 may be supplied to the low power load 1601.

In the first high power switch 1402, the first high power switching signal OUT_H1 is received by a gate, and one end is connected to the first storage device 1201 and the other end is connected to the high power load 1602. For example, when the first high power switching signal OUT_H1 received by a gate is a high level signal, the power charged to the first storage device 1201 may be supplied to the high power load 1602.

In the second low power switch 1403, the second low power switching signal OUT_L2 is received by a gate, and one end is connected to the second storage device 1204 and the other end is connected to the low power load 1601. For example, when the second low power switching signal OUT_L2 received by a gate is a high level signal, the power charged to the second storage device 1204 may be supplied to the low power load 1601.

In the second high power switch 1404, the second high power switching signal OUT_H2 is received by a gate, and one end is connected to the second storage device 1204 and the other end is connected to the high power load 1602. For example, when the second high power switching signal OUT_H2 received by a gate is a high level signal, the power charged to the second storage device 1204 may be supplied to the high power load 1602.

In the third low power switch 1405, the third low power switching signal OUT_L3 is received by a gate, and one end is connected to the third storage device 1207 and the other end is connected to the low power load 1601. For example, when the third low power switching signal OUT_L3 received by a gate is a high level signal, the power charged to the third storage device 1207 may be supplied to the low power load 1601.

In the third high power switch 1406, the third high power switching signal OUT_H3 is received by a gate, and one end is connected to the third storage device 1207 and the other end is connected to the high power load 1602. For example, when the third high power switching signal OUT_H3 received by a gate is a high level signal, the power charged to the third storage device 1207 may be supplied to the high power load 1602.

In an excess power switch SW_HE 1407, an excess switching signal OUT_HE is received by a gate, and one end is connected to the high power load 1601 and the other end is connected to an excess power load 1603. For example, when the excess power switching signal OUT_HE received by a gate is a high level signal, the power charged to the storage device may be supplied to the excess power load 1603.

For example, the first to third low power switches 1401, 1403, and 1405, the first to third high power switches 1402, 1404, and 1406, and the excess power switch SW_HE 1407 may form the switching circuit 140 of FIG. 1.

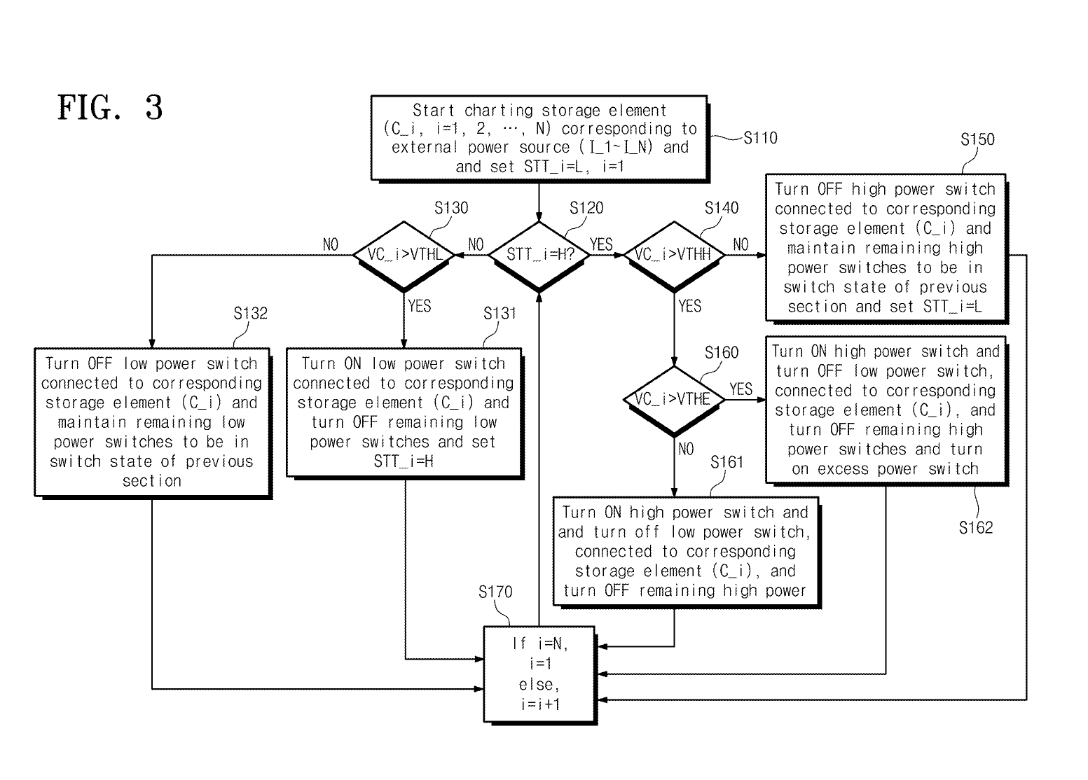

FIG. 3 is a flowchart illustrating a method of operating the power combining device 100 according to an embodiment of the inventive concept. State information SST_i corresponding to a selected external power source IN_i may be set to a high state or a low state according to a voltage VC_i of a storage device Ci charged by the selected external power source IN_i. Then, the power combining device 100 may activate at least one of a low power comparator and a high power comparator, which are connected to the selected external power source IN_i, according to the state information SST_i corresponding to the selected external power source IN_i.

Additionally, when the state information SST_i corresponding to the selected external power source IN_i is a high state, the power combining device 100 may activate an excess power comparator. An operation of the excess power comparator will be described in more detail with reference to FIG. 7.

For example, when the state information SST_1 of the first external power source IN_1 is a low state, the power combining device 100 may activate the first low power comparator 1202 by adjusting the first low power control signal CTR_L1 to a high level. Simultaneously, the power combining device 100 may deactivate the first high power comparator 1203 by adjusting the first high power control signal CTR_H1 to a low level. Additionally, the power combining device 100 may deactivate the excess power comparator 1220 by adjusting the excess signal ECEN to a low level.

On the other hand, when the state information SST_1 of the first external power source IN_1 is a high state, the power combining device 100 may deactivate the first low power comparator 1202 by adjusting the first low power control signal CTR_L1 to a low level. Simultaneously, the power combining device 100 may activate the first high power comparator 1203 by adjusting the first high power control signal CTR_H1 to a high level. Additionally, the power combining device 100 may activate the excess power comparator 1220 by adjusting the excess signal ECEN to a high level.

In a case that the state information SST_i corresponding to the selected external power source IN_i is a low state, when the level of the voltage VC_i of the storage device Ci charged by the selected external power source IN_i exceeds the first threshold voltage VTHL, the power combining device 100 may turn on the selected low power switch SW_Li by outputting the low power comparison signal C_Li in high level, which is outputted by a low power comparator corresponding to the selected external power source IN_i. In the same manner, in a case that the state information SST_i corresponding to the selected external power source IN_i is a high state, when the level of the voltage VC_i of the storage device Ci charged by the selected external power source IN_i exceeds the second threshold voltage VTHH, the power combining device 100 may turn on the selected high power switch SW_Hi by outputting the high power comparison signal C_Hi in high level, which is outputted by a high power comparator corresponding to the selected external power source IN_i.

Additionally, in a case that the state information SST_i corresponding to the selected external power source IN_i is a high state, when the level of the voltage VC_i of the storage device Ci charged by the selected external power source IN_i exceeds the third threshold voltage VTHE, the power combining device 100 may turn on the excess power switch SW_HE 1407 by outputting the excess power comparison signal HEO in high level, which is outputted by the excess power comparator 1220.

Additionally, the power combining device 100 may separately control the turn-on and turn-off operations of the low power switch SW_Li corresponding to the selected external power source IN_i and the turn-on and turn-off operations of the high power switches SW_Hk (i≠k) corresponding to the remaining external power sources IN_k (i≠k).

In the same manner, the power combining device 100 may separately control the turn-on and turn-off operations of the high power switch SW_Hi corresponding to the selected external power source IN_i and the turn-on and turn-off operations of the low power switches SW_Lk (i≠k) corresponding to the remaining external power sources IN_k (i≠k).

Additionally, in a state that the low power switch SW_Li corresponding to the selected external power source IN_i maintains a turn-on operation, when the high power switch SW_Hi corresponding to the selected external power source IN_i performs a turn-on operation, the power combining device 100 may subordinately turn off the low power switch SW_Li corresponding to the selected external power source IN_i. For example, in a state that the first low power switch SW_L1 corresponding to the first external power source IN_1 maintains a turn-on operation from a previous section, when the first high power switch SW_H1 corresponding to the first external power source IN_1 performs a turn-on operation, the first low power switch SW_L1 may perform a turn-off operation immediately.

When turning on the low power switch SW_Li connected to the storage device C_i charged by the selected external power source IN_i, the power combining device 100 may immediately turn off a switch that maintains a turn-on operation from a previous section among the remaining low power switches SW_Lk (k≠i).

In the same manner, when turning on the high power switch SW_Hi connected to the storage device C_i charged by the selected external power source IN_i, if there is a switch that maintains a turn-on operation from a previous section among the remaining high power switches SW_Hk (k≠i), the power combining device 100 may immediately turn off the switch.

Referring to FIGS. 1 to 3, in operation S110, the power combining device 100 may start to charge the storage devices C_1 to C_N disposed at an output terminal of each of the external power sources I_1 to I_N. For example, the power combining device 100 may charge the storage devices C_1 to C_N by turning off all the low power switches SW_L1 to SW_LN and the high power switches SW_H1 to SW_HN. Then, the power combining device 100 may initialize all the state information STT_1 to STT_N of the external power sources I_1 to I_N to a low state. Then, the power combining device 100 may initialize a variable i corresponding to the selected external power source IN_i.

In operation S120, the power combining device 100 may determine whether the state information STT_i of the selected external power sources IN_i is a high state. For example, when entering this operation immediately following operation S110, the method may enter operation S130 because the state information STT_1 of the first external power source IN_1 is a low state.

In operation S130, the power combining device 100 determines whether a level of the voltage VC_i of the storage device C_i corresponding to the selected external power source IN_i exceeds the first threshold voltage VTHL.

If a level of the voltage VC_i of the storage device C_i charged by the selected external power source IN_i exceeds the first threshold voltage VTHL, the power combining device 100 may perform operation S131. For example, a low power comparator activated according to a low state that is the state information SST_i of the selected external power source IN_i may output the selected low power comparison signal C_Li in high level.

In operation S131, the power combining device 100 may turn on the low power switch SW_Li selected based on the selected low power comparison signal C_Li for a connection time T. Accordingly, the storage device C_i charged by the selected external power source IN_i may be connected to the low power load 160a for the connection time T and supply power to it.

For example, the connection time T may be defined as twice the length of an interval t_c of signals outputted from the QC_N terminal and QC_N+1 terminal of a 2N bit Johnson counter.

Then, when turning on the selected low power switch SW_Li, if there is a switch that maintains a turn-on operation from a previous section among the remaining low power switches SW_Lk (k≠i), the power combining device 100 may immediately turn off the switch. Additionally, the power combining device 100 may set the state information STT_i of the selected external power source IN_i to a high state. Then, the power combining device 1000 may maintain the turn-on and turn-off operations of the high power switches SW_H1 to SW_HN for the connection time T as in a previous section. Then, operation S170 is performed.

If a level of the voltage VC_i of the storage device C_i corresponding to the selected external power source IN_i does not exceed the first threshold voltage VTHL, operation S132 may be performed. For example, a low power comparator activated according to a low state that is the state information SST_i of the selected external power source IN_i may output the selected low power comparison signal C_Li in low level.

In operation S132, the power combining device 100 may turn off the low power switch SW_Li selected based on the selected low power comparison signal C_Li for the connection time T. Simultaneously, the power combining device 100 may maintain the turn-on and turn-off operations of the remaining low power switches SW_Lk (k≠i) for the connection time T as in a previous section. Then, the power combining device 1000 may maintain the turn-on and turn-off operations of the high power switches SW_H1 to SW_HN for the connection time T as in a previous section. Then, operation S170 is performed.

In operation S140, when the state information STT_i of the selected external power source IN_i is a high state, the power combining device 100 determines whether a level of the voltage VC_i of the storage device C_i corresponding to the selected external power source IN_i exceeds the second threshold voltage VTHH.

If a level of the voltage VC_i of the storage device C_i charged by the selected external power source IN_i does not exceed the second threshold voltage VTHH, the power combining device 100 may perform operation S150. For example, a high power comparator activated according to a high state that is the state information SST_i of the selected external power source IN_i may output the selected high power comparison signal C_Hi in low level.

In operation S150, the power combining device 100 may turn off the high power switch SW_Hi selected based on the selected high power comparison signal C_Hi for the connection time T. Simultaneously, the power combining device 100 may maintain the turn-on and turn-off operations of the remaining high power switches SW_Hk (k≠i) for the connection time T as in a previous section. Additionally, the power combining device 100 may set the state information STT_i of the selected external power source IN_i to a low state. Then, the power combining device 1000 may maintain the turn-on and turn-off operations of the low power switches SW_L1 to SW_LN for the connection time T as in a previous section. Then, operation S170 is performed.

If a level of the voltage VC_i of the storage device C_i corresponding to the selected external power source IN_i exceeds the second threshold voltage VTHH, in operation S160, the power combining device 100 may determine whether a level of the voltage VC_i of the storage device C_i corresponding to the selected external power source IN_i exceeds the third threshold voltage VTHE.

If a level of the voltage VC_i of the storage device C_i corresponding to the selected external power source IN_i exceeds the second threshold voltage VTHH but a level of the voltage VC_i of the storage device C_i corresponding to the selected external power source IN_i does not exceed the third threshold voltage VTHE, in operation S161, a high power comparator activated according to a high state that is the state information SST_i of the selected external power source IN_i may output the selected high power comparison signal C_Hi in high level and the excess power comparator 1220 may output the excess power comparison signal HEO in low level.

Accordingly, the power combining device 100 may turn on the high power switch SW_Hi selected based on the selected high power comparison signal C_Hi and turn off the excess power switch SW_HE 1407 based on the excess power comparison signal HEO. Accordingly, the storage device C_i charged by the selected external power source IN_i may be connected to the high power load 160b for the connection time T and supply power to it. Then, when turning on the high power switch SW_Hi connected to the storage device C_i charged by the selected external power source IN_i, if there is a switch that maintains a turn-on operation in a previous section among the remaining high power switches SW_Hk (k≠i), the power combining device 100 may immediately turn off the switch. Additionally, in a state that the low power switch SW_Li corresponding to the selected external power source IN_i performs a turn-on operation, when the high power switch SW_Hi corresponding to the selected external power source IN_i performs a turn-on operation, the power combining device 100 may immediately turn off the low power switch SW_Li corresponding to the selected external power source IN_i. Then, the power combining device 100 may maintain the turn-on and turn-off operations of the remaining low power switches SW_Lk (k≠i) as in a previous section. Then, operation S170 is performed.

If a level of the voltage VC_i of the storage device C_i corresponding to the selected external power source IN_i exceeds the second threshold voltage VTHH and the third threshold voltage VTHE, in operation S162, a high power comparator activated according to a high state that is the state information SST_i of the selected external power source IN_i may output the selected high power comparison signal C_Hi in high level and the excess power comparator 1220 may output the excess power comparison signal HEO in high level.

Accordingly, the power combining device 100 may turn on the high power switch SW_Hi connected to the storage device C_i charged by the selected external power source IN_i based on the selected high power comparison signal C_Hi and turn on the excess power switch SW_HE 1407 based on the excess power comparison signal HEO. Accordingly, the storage device C_i charged by the selected external power source IN_i may be connected to the high power load 160b and the excess power load 160c for the connection time T and supply power to the excess power load 160c due to the load characteristics. Then, when turning on the high power switch SW_Hi connected to the storage device C_i charged by the selected external power source IN_i, if there is a switch that maintains a turn-on operation in a previous section among the remaining high power switches SW_Hk (k≠i), the power combining device 100 may immediately turn off the switch. Additionally, in a state that the low power switch SW_Li corresponding to the selected external power source IN_i performs a turn-on operation, when the high power switch SW_Hi corresponding to the selected external power source IN_i performs a turn-on operation, the power combining device 100 may immediately turn off the low power switch SW_Li corresponding to the selected external power source IN_i.

The high power load 160b and the excess power load 160c in the power combining device 100 may be connected in parallel to each other. For example, the excess power load 160c may be a device having a smaller impedance value than the high power load 160b. For example, the excess power load 160c may be a ground node. That is, when the excess power switch SW_HE 1407 is turned on, the supply power that the storage device C_i charged by the selected external power source IN_i delivers may be all delivered to the excess power load 160c due to the impedance size characteristics of the excess power load 160c Then, the power combining device 100 may maintain the turn-on and turn-off operations of the remaining low power switches SW_Lk (k≠i) as in a previous section. Then, operation S170 is performed.

When a variable i corresponding to the selected external power source IN_i is N, the power combining device 100 initializes the variable i to one. When the variable i corresponding to the selected external power source IN_i is not N, the power combining device 100 may increase the variable i by one.

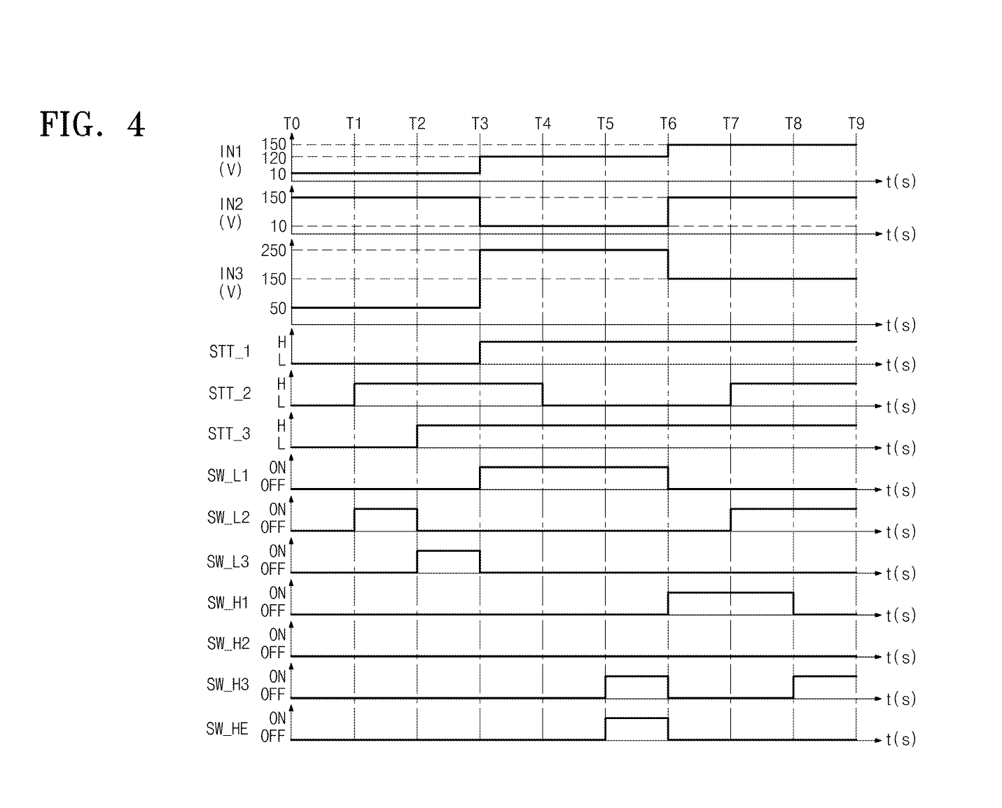

FIG. 4 is a timing diagram depending on an operation process according to an embodiment of the inventive concept. Referring to FIGS. 2 to 4, it is assumed that power is supplied from three external power sources IN_1 to IN_3. Then, it is assumed that a first threshold voltage VTHL is 20 V; a second threshold voltage VTHH is 100 V, and a third threshold voltage VTHE is 200 V. The horizontal axis of FIG. 4 is a time and configured with a first section T0 to T1 to a ninth section T8 to T9, and an interval of each section corresponds to a connection time T.

IN1(V) of the vertical axis of FIG. 4 is a voltage level of a first external power source, IN2(V) is a voltage level of a second external power source, and IN3(V) is a voltage level of a third external power source. Then, STT_1 of the vertical axis of FIG. 4 is state information of the first external power source IN_1 stored in the power combining device 1000, STT_2 is state information of the second external power source IN_2 stored in the power combining device 1000, and STT_3 is state information of the third external power source IN_3 stored in the power combining device 1000. Then, referring to FIG. 4, SW_L1 is an operating state of the first low power switch 1401 and SW_H1 is an operating state of the first high power switch 1402, SW_L2 is an operating state of the second low power switch 1403 and SW_H2 is an operating state of the second high power switch 1404, SW_L3 is an operating state of the third low power switch 1405 and SW_H3 is an operating state of the third high power switch 1406, and SW_HE is an operating state of the excess power switch 1407.

In the case of the T0 to T1 section, through operation S110 of FIG. 3, the state information STT_1, STT_2, and STT_3 of the first to third external power sources IN_1 to IN_3 are all initialized to a low state. Then, the power combining device 100 may activate the first low power determination comparator 1202 by adjusting the first low power control signal CTR_L1 to a high level in the T0 to T1 section of FIG. 4 and deactivate the first high power determination comparator 1203 by adjusting the first high power control signal CTR_H1 to a low level. That is, at the T0 time point, the power combining device 1000 may enter from operation S120 to operation S130 according to a low state that is the state information STT_1 of the first external power source IN_1 to perform the turn-on and turn-off operations of the first low power switch SW_L1 according to an output of the first low power determination comparator 1202.

For example, since 10 V that is the level of the voltage VC_1 of the first storage device C_1 does not exceed 20 V that is the first threshold voltage VTHL, the power combining device 1000 may turn off the low power switch SW_L1 connected to the storage device C_1 charged by the external power source IN_1 for the connection time T through operation S120, operation S130, and operation S132 of FIG. 3. Simultaneously, the power combining device 1000 may maintain the turn-on and turn-off operations of the remaining low power switches SW_L2 and SW_L3 for the connection time T as in the initial state T0. The power combining device 1000 maintains the state information STT_1, STT_2, and STT_3 of the first to third external power sources IN_1 to IN_3 in low state. At this point, the first to third high power switches SW_H1 to SW_H3 maintain the turn-off operations. Then, operation S170 is performed.

The power combining device 1000 may activate the second low power determination comparator 1205 by adjusting the second low power control signal CTR_L2 to a high level in the T1 to T2 section and deactivate the second high power determination comparator 1206 by adjusting the second high power control signal CTR_H2 to a low level.

Since the state information STT_2 of the second external power source IN_2 is a low state at the T1 time point, the power combining device 1000 may enter operation S130 to perform the turn-on and turn-off operations of the second low power switch SW_L2 1403 according to an output of the second low power determination comparator 1205.

For example, 150 V that is the level of the voltage VC_2 of the second storage device C_2 exceeds 20 V that is the first threshold voltage VTHL. At this point, in operation S130, the power combining device 1000 may output the second low power comparison signal C_L2 of the second low power determination comparator 1205 in high level and turn on the second low power switch SW_L2 1403 through operation S131. That is, the power combining device 100 may connect the second storage device C_2 charged by the second external power source IN_2 to the low power load 1601 for the connection time T and supply power to it.

Then, the power combining device 1000 sets the state information STT_2 of the second external power source IN_2 to a high state and maintains the state information STT_1 and STT_3 of the first and third external power sources IN_1 and IN_3 in low state. At this point, the turn-on and turn-off operations of the first low power switch SW_L1 1401, the third low power switch SW_L3 1405, and the first to third high power switches SW_H1 to SW_H3 are maintained as in the previous section T1 to T2. Then, operation S170 is performed.

The power combining device 1000 may activate the third low power determination comparator 1208 by adjusting the third low power control signal CTR_L3 to a high level in the T2 to T3 section and deactivate the third high power determination comparator 1209 by adjusting the third high power control signal CTR_H3 to a low level.

Since the state information STT_3 of the third external power source IN_3 is a low state at the T2 time point, the power combining device 1000 may enter operation S130 to perform the turn-on and turn-off operations of the third low power switch SW_L3 according to an output of the third low power determination comparator 1209.

For example, 50 V that is the level of the voltage VC_3 of the third storage device C_3 exceeds 20 V that is the first threshold voltage VTHL. At this point, in operation S130, the power combining device 1000 may output the third low power comparison signal C_L3 of the third low power determination comparator 1208 in high level and turn on the third low power switch SW_L3 1405 through operation S131. That is, the power combining device 1000 may connect the third storage device C_3 charged by the third external power source IN_3 to the low power load 1601 for the connection time T and supply power to it.

Then, when turning on the low power switch SW_L3 1405 connected to the third storage device C_3 charged by the third external power source IN_3, since there is the second low power switch SW_L2 1403 turned on in a previous section T1 to T2 among the remaining low power switches SW_L1 and SW_L2, the power combining device 1000 may immediately turn off the second low power switch SW_L2 1403. At this point, the first low power switch SW_L1 1401 and the first to third high power switches SW_H1 to SW_H3 maintain the turn-off operations. Then, the power combining device 1000 sets the state information STT_3 of the third external power source IN_3 to a high state and maintains the state information STT_1 and STT_2 of the first and second external power sources IN_1 and IN_2 as in the previous section T1 to T2.

The power combining device 1000 may activate the first low power determination comparator 1202 by adjusting the first low power control signal CTR_L1 to a high level in the T3 to T4 section and deactivate the first high power determination comparator 1203 by adjusting the first high power control signal CTR_H1 to a low level.

Since the state information STT_1 of the first external power source IN_1 is a low state at the T3 time point, the power combining device 1000 may enter operation S130 to perform the turn-on and turn-off operations of the first low power switch SW_L1 1401 according to an output of the first low power determination comparator 1202.

For example, 120 V that is the level of the voltage VC_1 of the first storage device C_1 exceeds 20 V that is the first threshold voltage VTHL. At this point, in operation S130, the power combining device 1000 may output the first low power comparison signal C_L1 of the first low power determination comparator 1202 in high level and turn on the first low power switch SW_L1 1401 through operation S131. That is, the power combining device 100 may connect the first storage device C_1 charged by the first external power source IN_1 to the low power load 1601 for the connection time T and supply power to it.

Then, when turning on the low power switch SW_L1 1401 connected to the first storage device C_1 charged by the first external power source IN_1, since there is the third low power switch SW_L3 1405 turned on in a previous section T2 to T3 among the remaining low power switches SW_L2 and SW_L3, the power combining device 1000 may immediately turn off the third low power switch SW_L3 1405. At this point, the second low power switch SW_L2 1403 and the first to third high power switches SW_H1 to SW_H3 maintain the turn-off operations. Then, the power combining device 1000 sets the state information STT_1 of the first external power source IN_1 to a high state and maintains the state information STT_2 and STT_3 of the second and third external power sources IN_2 and IN_3 as in the previous section T2 to T3.

The power combining device 1000 may deactivate the second low power determination comparator 1205 by adjusting the second low power control signal CTR_L2 to a low level in the T4 to T5 section and activate the second high power determination comparator 1206 by adjusting the second high power control signal CTR_H2 to a high level.

Since the state information STT_2 of the second external power source IN_2 is a high state at the T4 time point, the power combining device 1000 may enter operation S140 to perform the turn-on and turn-off operations of the second high power switch SW_H2 according to an output of the second high power determination comparator 1206.

For example, 10 V that is the level of the voltage VC_2 of the second storage device C_2 does not exceed 100 V that is the second threshold voltage VTHH. At this point, in operation S140, the power combining device 1000 may output the second high power comparison signal C_H2 of the second high power determination comparator 1206 in low level and turn off the second high power switch SW_H2 1404 through operation S150.

That is, the power combining device 100 may charge the second storage device C_2 connected to the output terminal of the second external power source IN_2 for the connection time T. Simultaneously, the power combining device 1000 may maintain the turn-on and turn-off operations of the remaining high power switches SW_H1 and SW_H3 for the connection time T as in the previous section T3 to T4. Additionally, the power combining device 1000 may maintain the turn-on and turn-off operations of the first to third low power switches SW_L1 to SW_L3 as in the previous section T3 to T4. Then, the power combining device 1000 sets the state information STT_2 of the second external power source IN_2 to a low state and maintains the state information STT_1 and STT_3 of the first and third external power sources IN_1 and IN_3 as in the previous section T3 to T4. Then, operation S170 is performed.

The power combining device 1000 may deactivate the third low power determination comparator 1208 by adjusting the third low power control signal CTR_L3 to a low level in the T5 to T6 section and activate the third high power determination comparator 1209 by adjusting the third high power control signal CTR_H3 to a high level.

Since the state information STT_3 of the third external power source IN_3 is a high state at the T5 time point, the power combining device 1000 may enter operation S140 to perform the turn-on and turn-off operations of the third high power switch SW_H3 according to an output of the third high power determination comparator 1209.

For example, 250 V that is the level of the voltage VC_3 of the third storage device C_3 exceeds 100 V that is the second threshold voltage VTHH and 200 V that is the third threshold voltage VTHE. At this point, in operation S140, the power combining device 1000 may output the third high power comparison signal C_H3 of the third high power determination comparator 1209 in high level and in operation S160, output the excess power comparison signal HEO of the excess power determination comparator 1220 in high level. Accordingly, in operation S161, the power combining device 1000 may turn on the third high power switch SW_H3 connected to the third storage device C_3 charged by the third external power source IN_3 based on the third high power comparison signal C_H3 and turn on the excess power switch SW_HE 1407 based on the excess power comparison signal HEO.

Additionally, the power combining device 1000 may maintain the turn-on and turn-off operations of the first to third low power switches SW_L1 to SW_L3 for the connection time T as in the previous section T4 to T5. Simultaneously, the power combining device 1000 may maintain the turn-on and turn-off operations of the first and second high power switches SW_H1 and SW_H2 for the connection time T as in the previous section T4 to T5. Accordingly, the third storage device C_3 charged by the third external power source IN_3 may be connected to the high power load 1602 and the excess power load 1603 for the connection time T and supply power to the excess power load 1603 due to the load characteristics.

The power combining device 1000 maintains the state information STT_1 to STT_3 of the first to third external power sources IN_1 to IN_3 as in the previous section T4 to T5.

The power combining device 1000 may deactivate the first low power determination comparator 1202 by adjusting the first low power control signal CTR_L1 to a low level in the T6 to T7 section and activate the first high power determination comparator 1203 by adjusting the first high power control signal CTR_H1 to a high level.

Since the state information STT_1 of the first external power source IN_1 is a high state at the T6 time point, the power combining device 1000 may enter operation S140 to perform the turn-on and turn-off operations of the first high power switch SW_H1 according to an output of the first high power determination comparator 1203.

For example, 150 V that is the level of the voltage VC_1 of the first storage device C_1 exceeds 100 V that is the second threshold voltage VTHH and does not exceed 200 V that is the third threshold voltage VTHE. Therefore, in operation S140, the power combining device 1000 may output the first high power comparison signal C_H1 of the first high power determination comparator 1203 in high level and in operation S160, output the excess power comparison signal HEO of the excess power determination comparator 1220 in low level. Accordingly, in operation S162, the power combining device 1000 may turn on the first high power switch SW_H1 connected to the first storage device C_1 charged by the first external power source IN_1 based on the first high power comparison signal C_H1 and turn off the excess power switch SW_HE 1407 based on the excess power comparison signal HEO.

Simultaneously, when turning on the high power switch SW_H1 1402 connected to the first storage device C_1 charged by the first external power source IN_1, since there is the third high power switch SW_H3 1406 turned on in a previous section among the remaining high power switches SW_H2 and SW_H3, the power combining device 1000 may immediately turn off the third high power switch SW_H3 1406.

Then, when turning on the high power switch SW_H1 1402 connected to the first storage device C_1 charged by the external power source IN_1, the power combining device 1000 may immediately turn off the first low power switch SW_L1 1401 that is turned on in a previous section. At this point, the turn-on and turn-off operations of the second and third low power switches SW_L2 and SW_L3 and the second high power switch SW_H2 are maintained as in the previous section T5 to T6.

Accordingly, the first storage device C_i charged by the first external power source IN_1 may be connected to the high power load 1602 for the connection time T and supply power to it. Additionally, the power combining device 1000 maintains the state information STT_1 to STT_3 of the first to third external power sources IN_1 to IN_3 as in the previous section T5 to T6.

The power combining device 1000 may activate the second low power determination comparator 1205 by adjusting the second low power control signal CTR_L2 to a high level in the T7 to T8 section and deactivate the second high power determination comparator 1206 by adjusting the second high power control signal CTR_H2 to a low level.

Since the state information STT_2 of the second external power source IN_2 is a low state at the T7 time point, in operation S130, the power combining device 1000 may perform the turn-on and turn-off operations of the second low power switch SW_L2 1403 according to an output of the second low power determination comparator 1205.

For example, 150 V that is the level of the voltage VC_2 of the second storage device C_2 exceeds 20 V that is the first threshold voltage VTHL. Therefore, in operation S130, the power combining device 1000 may output the second low power comparison signal C_L2 of the second low power determination comparator 1205 in high level and turn on the second low power switch SW_L2 1403 through operation S131. That is, the power combining device 100 may connect the second storage device C_2 charged by the second external power source IN_2 to the low power load 1601 for the connection time T and supply power to it.

Then, the power combining device 1000 may maintain the turn-on and turn-off operations of the first and third low power switches SW_L1 and SW_L3 as in the previous section T6 to T7. Simultaneously, the power combining device 1000 may maintain the turn-on and turn-off operations of the first too third high power switches SW_H1 to SW_H3 as in the previous section T6 to T7.

Additionally, the power combining device 1000 sets the state information STT_2 of the second external power source IN_2 to a high state and maintains the state information STT_1 and STT_3 of the first and third external powers IN_1 and IN_3 as in the previous section T6 to T7.

The power combining device 1000 may deactivate the third low power determination comparator 1208 by adjusting the third low power control signal CTR_L3 to a low level in the T8 to T9 section and activate the third high power determination comparator 1209 by adjusting the third high power control signal CTR_H3 to a high level.

Since the state information STT_3 of the third external power source IN_3 is a high state at the T8 time point, the power combining device 1000 may enter operation S140 to perform the turn-on and turn-off operations of the third high power switch SW_H3 according to an output of the third high power determination comparator 1209.

For example, 150 V that is the level of the voltage VC_3 of the third storage device C_3 exceeds 100 V that is the second threshold voltage VTHH and does not exceed 200 V that is the third threshold voltage VTHE. Therefore, in operation S140, the power combining device 1000 may output the third high power comparison signal C_H3 of the third high power determination comparator 1209 in high level and in operation S160, output the excess power comparison signal HEO of the excess power determination comparator 1220 in low level.

Accordingly, in operation S162, the power combining device 1000 may turn on the third high power switch SW_H3 1406 connected to the third storage device C_3 charged by the third external power source IN_3 based on the third high power comparison signal C_H3 and turn on the excess power switch SW_HE 1407 based on the excess power comparison signal HEO.

Simultaneously, when turning on the high power switch SW_H3 1406 connected to the third storage device C_3 charged by the third external power source IN_3, since there is the first high power switch SW_H1 1402 turned on in a previous section among the remaining high power switches SW_H1 and SW_H2, the power combining device 1000 may immediately turn off the first high power switch SW_H1 1402.

At this point, the power combining device 1000 may maintain the turn-on and turn-off operations of the first to third low power switches SW_L1 to SW_L3 as in the previous section T7 to T8. Then, the power combining device 1000 may maintain the turn-on and turn-off operations of the second high power switch SW_H2 as in the previous section T7 to T8.

Accordingly, the third storage device C_3 charged by the third external power source IN_3 may be connected to the high power load 1602 for the connection time T and supply power to it. Additionally, the power combining device 1000 maintains the state information STT_1 to STT_3 of the first to third external power sources IN_1 to IN_3 as in the previous section T7 to T8.

FIG. 5 is a view illustrating an internal logic circuit of the control circuit 150 or 1500 according to an embodiment of the inventive concept. Exemplarily, a case that N is three is shown in FIG. 5.

A process of generating first to third low power trigger signals LST_1 to LST_3 and the first to third high power trigger signals HST_1 to HST_3 will be described in detail with reference to FIGS. 1, 2, 3, and 5.

Based on a received system clock CLK, a frequency divider 161 generates a clock DCLK having a frequency that is half the frequency of the system clock CLK and output the generated clock DCLK to a 2N bit Johnson counter 162.

A time interval that control signals are outputted from an O_N terminal and Q_N+1 terminal of the 2N bit Johnson counter 162 corresponds to t_c and a time interval that control signals are outputted from the O_N terminal and the Q_N+1 terminal corresponds to a connection time T.

The 2N bit Johnson counter 162 receives a clock DCLK having a frequency that is half the frequency of the system clock CLK from the frequency divider 161 and outputs 2N signals. FIG. 5 illustrates a case that external power sources IN_1 to IN_3 are three (N=3) and thus, a total of six signals (that is, first to third low power control signals CTR_L1 to CTR_L3 and first to third high power control signals CTR_H1 to CTR_H3) are outputted. At this point, the first to third low power control signals CTR_L1 to CTR_L3 and the first to third high power control signals CTR_H1 to CTR_H3 are outputted to a comparison circuit 120, first to third low power D flip flops 163a, 164a, and 165a, and first to third high power D flip flops 163b, 164b, and 165b. The first to third low power D flip flops 163a, 164a, and 165a may receive the first to third low power control signals CTR_L1 to CTR_L3 to output the first to third low power trigger signals LST_1 to LST_3 to a switching generation circuit 130 according to the system clock CLK. Additionally, the first to third high power D flip flops 163b, 164b, and 165b may receive the first to third high power control signals CTR_H1 to CTR_H3 to output the first to third high power trigger signals HST_1 to HST_3 to the switching generation circuit 130 according to the system clock CLK. Since signals that are delayed by one clock than the system CLK are sequentially outputted by using a D flip flop, stabled signals may be outputted.

FIGS. 6 and 7 are views illustrating part of a generation logic of a switching generation circuit 130 or 1300 according to an embodiment of the inventive concept.

Referring to FIG. 6, a logic for generating a first low power switching signal OUT_L1 and a first high power switching signal OUT_H1 is shown. That is, according to the number N of external power sources, there may be N generation logics of a switching signal shown in FIG. 6.

Referring to FIGS. 1, 2, 3, 5, and 6, a first gate 131a outputs a result value LC_LS_OUT1 obtained by performing a logic operation based on a first low power comparison signal C_L1 outputted from a first low power determination comparator 1202 connected to a first external power source IN_1 and a value obtained by passing a signal HS_1 outputted from a third flip flop 132b through a NOT gate.

The first flip flop 132a outputs a signal LS_1 generated based on a first low power comparison signal C_L1 outputted from the first low power determination comparator 1202 and the first low power trigger signal LST_1 of FIG. 5.

A second gate 133a outputs a first low power switching release signal AR_1 by performing a logic operation based on the output value LC_LS_OUT1 of the first gate 131a and the first low power trigger signal LST_1 of FIG. 5. For example, when the first low power switch 1401 is turned on by the first external power source IN_1 and connected to the low power loads 160a and 1601, the first low power switching release signal AR_1 corresponds to a signal for immediately turning off the second and third low power switches 1403 and 1405 connected to the low power loads 160a and 160a in a previous section.

A second flip flop 134a outputs a signal LSW_inter1 generated based on the result value LC_LS_OUT1 of the first gate 131a and the first low power trigger signal LST_1. Additionally, an asynchronous reset terminal of the second flip flop 134a may receive a result value obtained by performing a logic operation on the low power switching release signal AR_k generated from the low power switching signal generation logic of the remaining external power sources IN_k, (k≠i) through the first NOR operation circuit 135a.

For example, in the case of FIG. 3, the asynchronous reset terminal of the second flip flop 134a may receive a result value obtained by performing a logic operation on the second and third low power switching release signals AR_2 and AR_3 through the first NOR operation circuit 135a, which are generated from the low power switching signal generation logics of the external power sources IN_2 and IN_3 other than the first external power source IN_1.

A third gate 136a outputs a first low power switching signal OUT_L1 obtained by performing a logic operation based on an output value LSW_inter1 of the second flip flop 134a and a value passing a signal HS_1 outputted from the third flip flop 132b through a NOT gate.

A fourth gate 131b outputs a result value HC_HS_OUT1 obtained by performing a logic operation based on the first high power comparison signal C_H1 outputted from the first high power determination comparator 1203 connected to the first external power source IN_1 and the output value LS_1 of the first flip flop 1321.

A third flip flop 132b outputs a signal HS_1 generated based on the output value HC_HS_OUT1 of the fourth gate 131b and the first high power trigger signal HST_1 of FIG. 5.

A fifth gate 133b outputs a first high power switching release signal ARH_1 obtained by performing a logic operation based on the output value HC_HS_OUT1 of the fourth gate 131b and the first high power trigger signal HST_1 of FIG. 5. When the first high power switch 1402 is turned on by the first external power source IN_1 and connected to the high power loads 160b and 1602, the high power switching release signal ARH_1 corresponds to a signal for turning off the second and third high power switches 1404 and 1406 of the other external power sources IN_1 and IN_3 connected to the high power loads 160b and 1602 in a previous section.

A fourth flip flop 134b outputs a first high power switching signal OUT_H1 obtained by performing a logic operation based on the output value HC_HS_OUT1 of the fourth gate 131b and the first high power trigger signal HST_1. Additionally, the asynchronous reset terminal of the fourth flip flop 134b may receive a result value obtained by performing a logic operation on a high power switching release signal ARH_k (k≠i) through a second NOR operation circuit 135b, which is generated from a high power switching signal generation logic of the remaining external power sources IN_k (k≠i).

For example, in the case of FIG. 3, the asynchronous reset terminal of the fourth flip flop 134b may receive a result value obtained by performing a logic operation on the second and third high power switching release signals ARH_2 and ARH_3 through the second NOR operation circuit 135b, which are generated from the high power switching signal generation logics of the external power sources IN_2 and IN_3 other than the first external power source IN_1.

At this point, the first to fourth flip flops may be D flip flops and the first to fifth gate may be AND logic gates.

Referring to FIG. 7, a logic for generating an excess power switching signal OUT_HE is shown. In this case, regardless of the number N of external power sources, a generation logic of an excess power switching signal may be one.

Referring to FIGS. 1, 2, 3, and 5, a first OR gate 131c outputs an excess signal ECEN by performing a logic operation on first to Nth high power control signals CTR_H1 to CTR_HN outputted from the 2N bit Johnson counter 162 of FIG. 5. Therefore, a level of the excess signal ECEN may be synchronized with levels of the first to Nth high power control signals CTR_H1 to CTR_HN and outputted.

A fifth flip flop 132c outputs an excess power trigger signal EST generated based on the excess signal that is the output value of the first OR gate 131c and a clock DCLK having a frequency that is half the frequency of the system clock CLK.

A sixth flip flop 132c outputs an excess power switching signal OUT_HE generated based on the excess power comparison signal HEO that is the output value of the excess power comparator 1220 and the excess power trigger signal EST outputted from the fifth flip flop 132c. At this point, the fifth and sixth flip flops may be D flip flops.

According to an embodiment of the inventive concept, a power combining device having improved efficiency is provided.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. A power combining device comprising:
a comparison circuit configured to output low power comparison signals by comparing a level of a first threshold voltage and levels of voltages of storage elements charged by external power sources according to low power control signals and output high power comparison signals by comparing a level of a second threshold voltage and the levels of the voltages according to high power control signals;
a switching signal generation circuit configured to output low power switching signals based on the low power comparison signals and output high power switching signals based on the high power comparison signals; and
a switching circuit configured to select loads electrically coupled with the storage elements based on the low power switching signals and the high power switching signals.

2. The power combining device of claim 1, wherein the comparison circuit comprises:
a first comparison unit configured to output a first low power comparison signal by comparing the level of the first threshold voltage and a level of a voltage of a first storage element charged by a first external power source according to a first low power control signal and output a first high power comparison signal by comparing the level of the second threshold voltage and the level of the voltage of the first storage element charged by the first external power source according to a first high power control signal; and
a second comparison unit configured to output a second low power comparison signal by comparing the level of the first threshold voltage and a level of a voltage of a second storage element charged by a second external power source according to a second low power control signal and output a second high power comparison signal by comparing the level of the second threshold voltage and the level of the voltage of the second storage device charged by the second external power source according to a second high power control signal.

3. The power combining device of claim 2, wherein the first comparison unit comprises:
a first low power determination comparator having a first input connected to the first storage element and a second input where the first threshold voltage is applied and configured to output the first low power comparison signal by comparing a level of a voltage charged in the first storage element and a level of the first threshold voltage in response to the first low power control signal; and
a first high power determination comparator having a third input connected to the first storage device and a fourth input where the second threshold voltage is applied and configured to output the first high power comparison signal by comparing the level of the voltage charged in the first storage device and the level of the second threshold voltage in response to the first high power control signal.

4. The power combining device of claim 2, wherein the switching signal generation circuit comprises:
a first flip flop configured to output a signal generated based on the first low power comparison signal and a first low power trigger signal;
a first gate configured to output a result value obtained by performing a logic operation based on the first low power comparison signal and a first signal;
a second gate configured to output a result value obtained by performing a logic operation based on an output value of the first gate and the first low power trigger signal;
a second flip flop configured to receive an output of a first NOR operation circuit through an asynchronous reset terminal and output a signal generated based on the output value of the first gate and the first low power trigger signal;
a third gate configured to output a first low power switching signal obtained by performing a logic operation based on an output value of the second flip flop and the first signal;
a fourth gate configured to output a result value obtained by performing a logic operation based on the first high power comparison signal and a value outputted from the first flip flop;
a third flip flop configured to output a signal generated based on an output value of the fourth gate and a first high power trigger signal;
a fifth gate configured to output a result value obtained by performing a logic operation based on the output value of the fourth gate and the first high power trigger signal; and
a fourth flip flop configured to receive an output of a second NOR operation circuit through an asynchronous reset terminal and output a first high power switching signal generated based on the output value of the fourth gate and the first high power trigger signal.

5. The power combining device of claim 4, wherein the first signal is a signal obtained by inverting a signal outputted from the third flip flop.

6. The power combining device of claim 4, wherein the first NOR operation circuit outputs a signal obtained through a NOR logic operation by receiving a plurality of low power switching release signals corresponding to external power sources other than the first external power source as an input.

7. The power combining device of claim 4, wherein the second NOR operation circuit outputs a signal obtained through a NOR logic operation by receiving a plurality of high power switching release signals corresponding to external power sources other than the first external power source as an input.

8. The power combining device of claim 4, wherein the first to sixth flip flops are D flip flops and each of the first to fifth gates comprises an AND gate.

9. The power combining device of claim 4, wherein the switching signal generation circuit further comprises:
a first OR operation circuit configured to an excess signal obtained by performing a logic operation on a plurality of high power control signals;
a fifth flip flop configured to output an excess power trigger signal generated based on the excess signal and a clock signal having a frequency that is half a frequency of a system clock signal; and
a sixth flip flop configured to output an excess power switching signal generated based on an excess power comparison signal outputted from an excess power comparator and an excess power trigger signal outputted from a fifth flip flop.

10. The power combining device of claim 2, wherein the second comparison unit comprises:
a second low power determination comparator having a first input connected to the second storage device and a second input where the first threshold voltage is applied and configured to output the second low power comparison signal by comparing a level of a voltage charged in the second storage device and a level of the first threshold voltage in response to a second low power control signal; and
a second high power determination comparator having a third input connected to the second storage device and a fourth input where the second threshold voltage is applied and configured to output the second high power comparison signal by comparing the level of the voltage charged in the second storage device and the level of the second threshold voltage outputted from a threshold voltage applying circuit in response to a second high power control signal.

11. The power combining device of claim 2, further comprising a third comparison unit configured to output a third low power comparison signal by comparing the level of the first threshold voltage and a level of a voltage of a third storage element charged by a third external power source according to a third low power control signal and output a third high power comparison signal by comparing the level of the second threshold voltage and the level of the voltage of the third storage device charged by the third external power source according to a third high power control signal.

12. The power combining device of claim 11, wherein the first to third storage elements are capacitors.

13. The power combining device of claim 2, further comprising an excess power comparator, when a high power load among the loads is electrically coupled with an storage element among the storage elements, configured to output an excess power comparison signal by comparing a level of a third threshold voltage and a level of a voltage applied to the high power load according to an excess signal.

14. The power combining device of claim 13, wherein when the voltage applied to the high power load is greater than the third threshold voltage, an excess power switch is turned on for electrically coupling the storage element and an excess power load according to the excess power comparison signal.

15. The power combining device of claim 2, wherein the first comparison unit receives one signal of the first low power control signal and the first high power control signal in a high level according to state information of the first external power source and activates one of the first low power determination comparator and the first high power determination comparator according to the one signal received in the high level.

16. The power combining device of claim 1, wherein the switching circuit comprises:
a first low power switch having a first input connected to a first storage element charged by first external power sources and a second input connected to a low power load and connecting the first storage element and the low power load based on a first low power switching signal outputted from the switching signal generation circuit; and
a first high power switch having a third input connected to the first storage element and a fourth input connected to a high power load and connecting the first storage element and the high power load based on a first high power switching signal outputted from the switching signal generation circuit.

17. The power combining device of claim 16, wherein the switching circuit comprises:
a second low power switch having a first input connected to a second storage element charged by second external power sources and a second input connected to a low power load and connecting the second storage element and the low power load based on a second low power switching signal outputted from the switching signal generation circuit; and
a second high power switch having a third input connected to the second storage element and a fourth input connected to a high power load and connecting the second storage element and the high power load based on a second high power switching signal outputted from the switching signal generation circuit.

18. The power combining device of claim 1, further comprising an excess power switch having a first input connected to a high power load and a second input connected to an excess power load and connecting a storage element among elements charged by the external power sources with the excess power load based on an excess power switching signal outputted from the switching signal generation circuit.

19. The power combining device of claim 18, wherein the excess power load has a smaller impedance value than the high power load.
